(19) United States
(12) Patent Application Publication
(10) Pub. No.: US 2021/0183629 A1
(43) Pub. Date: Jun. 17, 2021

(54) RING ASSEMBLY, SUBSTRATE SUPPORT ASSEMBLY AND SUBSTRATE PROCESSING APPARATUS

(71) Applicant: Tokyo Electron Limited, Tokyo (JP)

(72) Inventors: Kazuki OSHIMA, Miyagi (JP); Shingo OGUMA, Miyagi (JP)

(73) Assignee: Tokyo Electron Limited, Tokyo (JP)

(21) Appl. No.: 17/117,177

(22) Filed: Dec. 10, 2020

(30) Foreign Application Priority Data
Dec. 13, 2019 (JP) 2019-225271

(51) Int. Cl. H01J 37/32

(52) U.S. Cl. CPC H01J 37/32642; H01L 21/68735; H01J 37/32715

(57) ABSTRACT

Provided is a technique capable of adjusting an angle of incidence of ions. Provided is a ring assembly including: a conductive edge ring; an insulating annular member including at least an inner peripheral portion disposed on the edge ring; and a conductive member disposed on at least a portion of an upper surface of the annular member overlapping with the edge ring in top plan view.

### CROSS-REFERENCE TO RELATED APPLICATION

This application claims the benefit of Japanese Patent Application No. 2019-225271 filed on Dec. 13, 2019, the entire disclosures of which are incorporated herein by reference.

### TECHNICAL FIELD

The present disclosure relates to a ring assembly, a substrate support assembly, and a substrate processing apparatus.

### BACKGROUND ART

JP-A-2018-129386 discloses a plasma processing apparatus including a processing chamber and a substrate support which is provided in the processing chamber and on which a target object is disposed. The plasma processing apparatus described in JP-A-2018-129386 has an edge ring provided on the substrate support so as to surround the target object and an annular member disposed so as to surround the outer peripheral surface of the edge ring. JP-A-2014-090177 discloses a process kit which is mounted near a workpiece in a semiconductor manufacturing process plasma chamber. The process kit described in JP-A-2014-090177 is made of a dielectric material, has a dielectric shield which has a central opening portion and of which outer edge is outside the outer edge of the workpiece, and has a conductive collar which has a central opening portion and of which outer edge is outside the outer edge of the workpiece. The conductive collar described in JP-A-2014-090177 overlies on at least a portion of the dielectric shield.

### SUMMARY

According to one aspect of the disclosure, there is provided a ring assembly including a conductive edge ring, an insulating annular member including at least an inner peripheral portion disposed on the edge ring, and a conductive member disposed on at least a portion of an upper surface of the annular member overlapping with the edge ring in top plan view.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

FIG. 1 is a cross-sectional view illustrating a schematic configuration of a substrate processing apparatus according to an embodiment.

FIG. 2 is a cross-sectional view illustrating a ring assembly according to the embodiment.

FIG. 3 is a cross-sectional view of Modified Example of the ring assembly according to the embodiment.

FIG. 4 is a cross-sectional view of Modified Example of the ring assembly according to the embodiment.

FIG. 5 is a cross-sectional view of a ring assembly according to Comparative Example.

### DESCRIPTION OF EMBODIMENTS

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the disclosure will be described with reference to the drawings. In addition, in this specification and the drawings, substantially the same configurations will be denoted by the same or corresponding reference numerals to omit redundant description.

<Substrate Processing Apparatus>

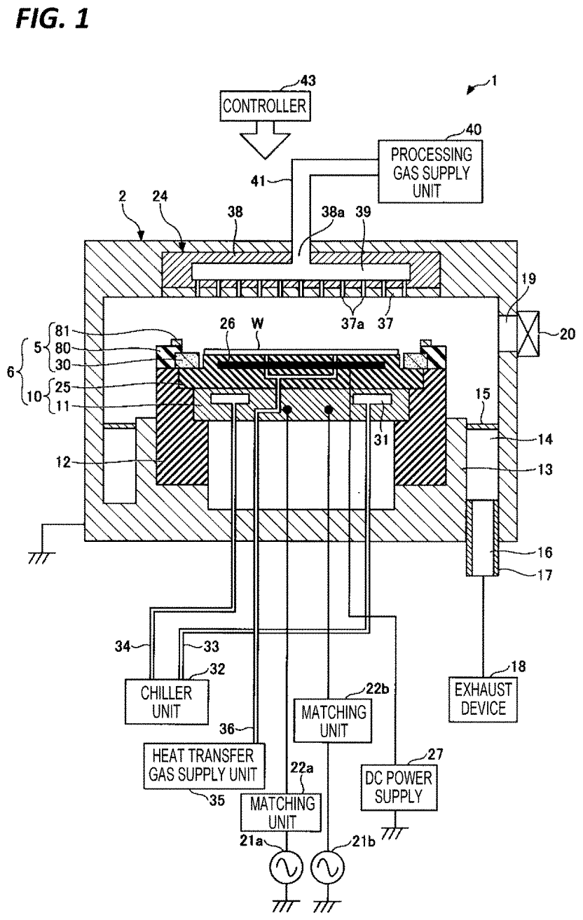

First, an example of an overall configuration of a substrate processing apparatus 1 will be described with reference to FIG. 1. FIG. 1 is a cross-sectional view illustrating a schematic configuration of the substrate processing apparatus 1 according to the embodiment. In addition, in the embodiment, an example where the substrate processing apparatus 1 is a reactive ion etching (RIE) type substrate processing apparatus will be described. However, the substrate processing apparatus 1 may be, for example, a plasma etching apparatus or a plasma chemical vapor deposition (CVD) apparatus.

In FIG. 1, the substrate processing apparatus 1 has a grounded cylindrical processing chamber 2 made of metal, for example, aluminum or stainless steel. A disc-shaped substrate support 10 on which a substrate W is supported is provided inside the processing chamber 2. The substrate support 10 includes a base 11 and an electrostatic chuck 25. The base 11 functions as a lower electrode. The base 11 is made of, for example, aluminum. The base 11 is supported by a cylindrical support portion 13 extending vertically upward from the bottom of the processing chamber 2 via an insulating cylindrical holding member 12.

An exhaust passage 14 is formed between the side wall of the processing chamber 2 and the cylindrical support portion 13. An annular baffle plate 15 is arranged at the inlet or midway of the exhaust passage 14, and an exhaust port 16 is provided at the bottom. An exhaust device 18 is connected to the exhaust port 16 via an exhaust pipe 17. Herein, the exhaust device 18 has a dry pump and a vacuum pump and decompresses a processing space in the processing chamber 2 to a predetermined degree of vacuum. In addition, a gate valve 20 is attached to the side wall of the processing chamber 2 to open and close a loading/unloading port 19 for the substrate W.

A first radio frequency power supply 21a is connected to the base 11 via a first matching unit 22a. In addition, a second radio frequency power supply 21b is connected to the base 11 via a second matching unit 22b. The first radio frequency power supply 21a supplies a radio frequency power for plasma generation having a predetermined frequency (for example, 100 MHz) to the base 11. The second radio frequency power supply 21b supplies a radio frequency power for ion attraction having a predetermined frequency (for example, 13 MHz) lower than that of the first radio frequency power supply 21a to the base 11.

A shower head 24 which also functions as an upper electrode is provided on the ceiling of the processing chamber 2. Accordingly, radio frequency voltages of two frequencies from the first radio frequency power supply 21a and the second radio frequency power supply 21b are applied between the base 11 and the shower head 24.

The electrostatic chuck 25 that attracts the substrate W by an electrostatic force is provided on the upper surface of the base 11. The electrostatic chuck 25 is configured by interposing an electrode plate 26 made of a conductive film between a pair of dielectric films. A DC power supply 27 is electrically connected to the electrode plate 26. The DC power supply 27 applies a DC voltage to the electrode plate 26 under the control of a controller 43 (to be described later). The electrostatic chuck 25 generates an electrostatic force such as a Coulomb force by the voltage applied to the electrode plate 26 from the DC power supply 27 and attracts and holds the substrate W to the electrostatic chuck 25 by the electrostatic force.

A flow channel 31 is provided in the base 11. A heat exchange medium (for example, a coolant) is supplied from a chiller unit 32 to the flow channel 31 via pipes 33 and 34, and the processing temperature of the substrate W on the electrostatic chuck 25 is controlled by the temperature of the heat exchange medium.

In addition, a heat transfer gas supply unit 35 is connected to the electrostatic chuck 25 via a gas supply line 36. The heat transfer gas supply unit 35 supplies the heat transfer gas to a space interposed between the electrostatic chuck 25 and the substrate W via the gas supply line 36. Examples of the heat transfer gas include a gas having thermal conductivity, for example, He gas.

The shower head 24 on the ceiling has an electrode plate 37 on the lower surface having a plurality of gas injection holes 37a and an electrode support 38 that detachably supports the electrode plate 37. A diffusion space 39 is provided inside the electrode support 38, and a processing gas supply unit 40 is connected to a gas inlet 38a communicating with the diffusion space 39 via a gas supply pipe 41.

Each component of the substrate processing apparatus 1 is connected to the controller 43. For example, the exhaust device 18, the first radio frequency power supply 21a, the second radio frequency power supply 21b, the DC power supply 27, the chiller unit 32, the heat transfer gas supply unit 35, and the processing gas supply unit 40 are connected to the controller 43. The controller 43 controls each component of the substrate processing apparatus 1.

The controller 43 includes a central processing unit (CPU) (not illustrated) and a storage device such as a memory and allows the substrate processing apparatus 1 to execute each processing by reading a program and a processing recipe stored in the storage device.

In the substrate processing apparatus 1, an insulating annular member 80 is provided outside an edge ring 30. In addition, a conductive member 81 is provided on the upper surface of the insulating annular member 80. In some cases, a combination of the edge ring 30, the insulating annular member 80, and the conductive member 81 may be referred to as a ring assembly 5. In addition, the details of the ring assembly 5 will be described later. A combination of the ring assembly 5 and the substrate support 10 may be referred to as a substrate support assembly 6 in some cases.

In the substrate processing apparatus 1, during the dry etching process, first, the gate valve 20 is set to the opened state, so that the substrate W to be processed is loaded into the processing chamber 2 and supported on the electrostatic chuck 25. Then, in the substrate processing apparatus 1, a processing gas (for example, a mixed gas containing C₄F₈ gas, O₂ gas, and Ar gas) is introduced into the processing chamber 2 from the processing gas supply unit 40 at a predetermined flow rate and a predetermined flow rate ratio, and the pressure in the processing chamber 2 is set to a predetermined value by, for example, the exhaust device 18.

Furthermore, in the substrate processing apparatus 1, radio frequency powers having different frequencies are supplied from the first radio frequency power supply 21a and the second radio frequency power supply 21b to the base 11. In addition, in the substrate processing apparatus 1, a DC voltage is applied from the DC power supply 27 to the electrode plate 26 of the electrostatic chuck 25 to attract the substrate W to the electrostatic chuck 25. The processing gas injected from the shower head 24 is turned into plasma, and the substrate W is etched by radicals and ions in the plasma.

<Ring Assembly>

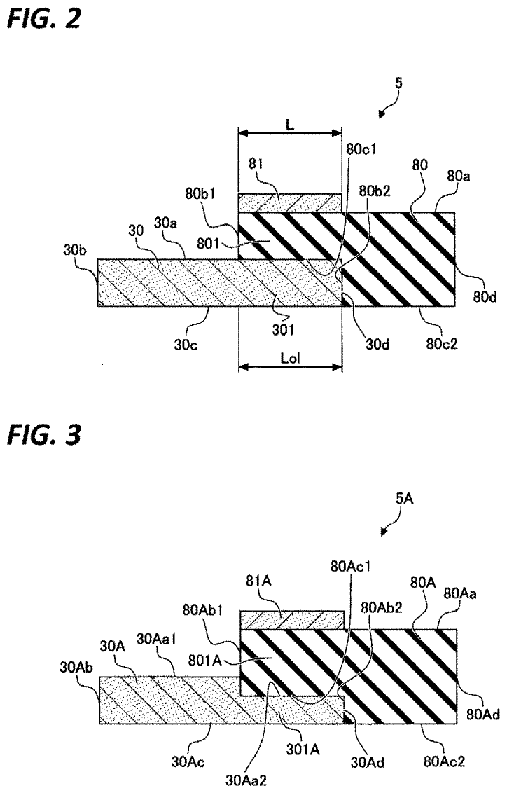

The ring assembly 5 according to the embodiment will be described in detail. FIG. 2 is a cross-sectional view of the ring assembly 5 according to the embodiment.

The ring assembly 5 includes the edge ring 30, the annular member 80, and the conductive member 81.

The edge ring 30 is an annular member. The edge ring 30 is made of a conductive material. The edge ring 30 is made of, for example, the same material as the substrate W. Specifically, the edge ring 30 is made of, for example, silicon (Si) or silicon carbide (SiC). Each surface of the edge ring 30 will be described. An upper surface 30a of the edge ring 30 is a surface exposed to plasma. An inner peripheral surface 30b of the edge ring 30 is a surface on the substrate W side supported on the electrostatic chuck 25. A lower surface 30c of the edge ring 30 is a surface to be supported on the substrate support 10. An outer peripheral surface 30d of the edge ring 30 is a surface opposite to the substrate W supported on the electrostatic chuck 25.

The annular member 80 is disposed so as to cover an outer peripheral portion 301 of the edge ring 30. The inner diameter of the annular member 80 is larger than the inner diameter of the edge ring 30 so that the annular member 80 covers the outer peripheral portion 301 of the edge ring 30. In other words, the inside of the outer peripheral portion 301 (the left portion) of the edge ring 30 is not covered with the annular member 80, as illustrated in, for example, FIG. 2. The annular member 80 is made of an insulating material. Specifically, the annular member 80 is made of, for example, silicon oxide (SiO₂). Each surface of the annular member 80 will be described. An upper surface 80a of the annular member 80 is a surface exposed to the plasma. An inner peripheral surface 80b1 of the annular member 80 is a surface on the substrate W side supported on the electrostatic chuck 25. A lower surface 80c1 of the annular member 80 is a surface facing the upper surface 30a of the edge ring 30 and being disposed on the upper surface 30a of the edge ring 30. An inner peripheral surface 80b2 of the annular member 80 is a surface that covers the outer peripheral surface 30d of the edge ring 30. A lower surface 80c2 of the annular member 80 is a surface supported on the substrate support 10. An outer peripheral surface 80d of the annular member 80 is a surface on the opposite side to the substrate W supported on the electrostatic chuck 25.

The conductive member 81 is an annular member disposed on the substrate W side of the upper surface 80a of the annular member 80. The conductive member 81 is provided from the end portion of the upper surface 80a of the annular member 80 on the inner peripheral surface 80b1 side. That is, the inner diameter of the annular member 80 and the inner diameter of the conductive member 81 are equal to each other. In this manner, the conductive member 81 covers the upper surface 80a of the annular member 80 overlapping with the edge ring 30 within a predetermined range from the inner diameter side. In addition, the radial width of the conductive member 81 is equal to the radial width of the overlapping portion between the edge ring 30 and the annular member 80. Accordingly, the outer diameter of the conductive member 81 is smaller than the outer diameter of the annular member 80. The radial dimension of the overlapping portion between the edge ring 30 and the annular member 80 is set as Lol, and the radial dimension from the end portion of the conductive member 81 on the inner peripheral surface 80b1 side is set as L. In the ring assembly 5 according to the embodiment, the length Lol and the length L are equal to each other. In addition, the length L may not be the same as the length Lol, and it is preferably that the length L is, for example, half or more of the length Lol. The conductive member 81 is made of a conductive material. Specifically, the conductive member 81 is made of, for example, silicon (Si) or silicon carbide (SiC).

<Function and Effect>

As illustrated in FIG. 2, the upper surface 30a of the outer peripheral portion 301 of the edge ring 30 is covered with the annular member 80. That is, in the annular member 80, an inner peripheral portion 801 is disposed on the edge ring 30. In a case where the edge ring 30 is not covered with another member, as compared with the inner peripheral surface 30b side, the outer peripheral surface 30d side is worn out particularly quickly. In the ring assembly 5 according to the embodiment, the outer peripheral surface 30d side (outer peripheral portion 301) of the edge ring 30 is covered with the annular member 80. Accordingly, it is possible to suppress the wear out of the outer peripheral surface 30d side (outer peripheral portion 301) of the edge ring 30.

In addition, the conductive member 81 is provided on the annular member 80, so that it is possible to reduce the wear out of the annular member 80. In particular, the conductive member 81 covers at least the upper surface 80a of the annular member 80 from the inner diameter side. In this manner, it possible to suppress the wear out of the annular member 80 and the edge ring 30 due to the plasma.

Furthermore, the conductive member 81 is arranged on at least a portion of the upper surface 80a of the annular member 80, which overlaps with the edge ring 30 in top plan view. Accordingly, the height of the upper surface 80a of the annular member 80 and the height of an upper surface 81a of the conductive member 81 from the substrate support 10 are higher than the height of the upper surface 30a of the edge ring 30. The height of the upper surface 80a of the annular member 80 and the height of the upper surface 81a of the conductive member 81 from the substrate support 10 are heightened, so that the height of the sheath in the edge ring 30 and the annular member 80 is allowed to be higher than that of the sheath formed on the upper surface 30a of the edge ring 30. By adjusting the height of the sheath in this manner, it is possible to adjust the angle of incidence of the ions that are incident on the periphery of the end portion of the substrate W and control the etching shape of the end portion of the substrate W. For example, in a case where the angle of incidence of ions is inclined inward in the initial state, the angle of incidence of ions can be adjusted vertically by applying the ring assembly 5 according to the embodiment.

In addition, the conductive member 81 is provided on the annular member 80, so that the distance between the upper surface 81a of the conductive member 81 and the upper electrode (shower head 24) can be narrowed. Accordingly, since the plasma can be confined to the substrate W side, it is possible to suppress a decrease in the plasma density.

In the substrate processing apparatus 1, the edge ring 30 and the annular member 80 are consumable parts that need to be replaced according to the usage time. The productivity is decreased because the apparatus is stopped during the replacement work of the consumable parts. In the ring assembly 5 according to the embodiment, the wear out of the annular member 80 and the edge ring 30 due to the plasma is suppressed, so that it is possible to lengthen the replacement cycle and increase the life cycle of the consumable parts. In addition, it is possible to improve the productivity by increasing the operating rate of the apparatus.

Herein, a ring assembly 5Z according to Comparative Example will be described. FIG. 5 is a cross-sectional view of the ring assembly 5Z according to Comparative Example. In the ring assembly 5Z according to Comparative Example, annular members 80Z are provided side by side outside an edge ring 30Z. The heights of an upper surface 30Za of the edge ring 30Z and an upper surface 80Za of the annular member 80Z from the substrate support 10 are the same as each other. In that case, for example, when the upper surface 30Za of the edge ring 30Z is worn out, the height of the sheath is shortened. When the upper surface 30Za of the edge ring 30Z is worn out and the height of the sheath is shortened, the angle of incidence of ions of the periphery of the end portion of the substrate W is changed. Meanwhile, in the ring assembly 5 according to the embodiment, the angle of incidence of ions is adjusted to a desired substantially vertical angle, and the annular member 80 and the conductive member 81 are provided. Therefore, as compared with a case where the annular member 80 and the conductive member 81 are not provided, the distance between the annular member 80 and the upper electrode (shower head 24) and the distance between the conductive member 81 and the upper electrode can be shortened. Accordingly, the function of confining the plasma inside the edge ring 30 can be enhanced, and thus, it is possible to suppress the decrease in plasma density. It is possible to achieve both the adjustment of the angle of incidence of the ions and the suppression of the decrease in the plasma density.

In addition, for example, silicon oxide which is the material of the annular member 80 has an etching rate with respect to plasma of about eight times faster than that of silicon which is the material of the conductive member 81. Therefore, the annular member 80 made of silicon oxide is likely to be worn out. In particular, the substrate W side (inner peripheral portion 801) where the annular member 80 overlaps with the edge ring 30 is likely to be etched. This is because the collision energy of the plasma is large in the portion overlapping with the edge ring 30. In the ring assembly 5 according to the embodiment, the conductive member 81 is provided in the portion overlapping with the edge ring 30, so that the wear out of the annular member 80 can be suppressed. Therefore, the replacement cycle of the annular member 80 and the edge ring 30 can be lengthened.

### MODIFIED EXAMPLE 1

FIG. 3 is a cross-sectional view of a ring assembly 5A that is Modified Example of the ring assembly 5 according to the embodiment.

In the ring assembly 5A, an outer peripheral portion 301A of an edge ring 30A becomes thin. Specifically, an upper surface 30Aa1 is higher than an upper surface 30Aa2. In an annular member 80A, a portion (inner peripheral portion 801A) that overlaps with the edge ring 30A with respect to the annular member 80 becomes thick. In addition, a conductive member 81A is provided on an upper surface 80Aa of the annular member 80A. The conductive member 81A covers the entire upper surface of the annular member 80A that overlaps with the edge ring 30A in top plan view.

In this manner, by allowing the outer peripheral portion 301A of the edge ring 30A to be thin to provide a step difference, it is possible to achieve adjustment of the angle of incidence of ions and suppression of the decrease in the plasma density as in the above-described embodiment. Furthermore, it is possible to easily perform position alignment of the edge ring 30A and the annular member 80A.

### MODIFIED EXAMPLE 2

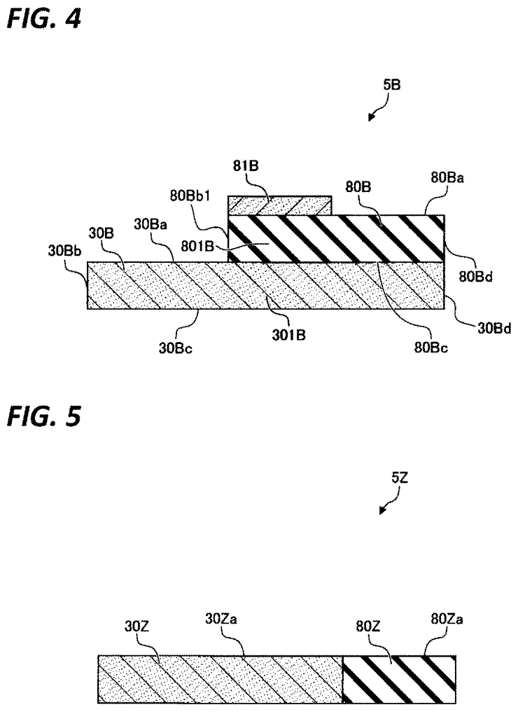

FIG. 4 is a cross-sectional view of a ring assembly 5B that is Modified Example of the ring assembly 5 according to the embodiment.

In the ring assembly 5B, an annular member 80B is provided on an upper surface 30Ba of an edge ring 30B. In addition, a conductive member 81B is provided on an upper surface 80Ba of the annular member 80B.

As described above, the annular member 80B is provided on the upper surface 30Ba of the edge ring 30B, so that it is possible to further increase the radial size of the edge ring 30B. The conductive member 81B covers a portion of the upper surface of the annular member 80B that overlaps with the edge ring 30B in top plan view. The range in which the conductive member 81B covers the annular member 80B may be determined according to the worn-out state of the annular member 80B. The substrate W side of the annular member 80B, which overlaps with the edge ring 30, is likely to be etched. Therefore, the inside of the conductive member 81B, which is likely to be etched, is covered with the conductive member 81B. In addition, since the product occurring in the process is deposited on the outside of the annular member 80B, the outside of the annular member 80B may not be covered with the conductive member 81B.

### MODIFIED EXAMPLE

Although the conductive member 81 according to the embodiment has an annular shape, the shape is not limited thereto. For example, an arc-shaped conductive member 81 may be provided in a portion in the circumferential direction according to the angle of incidence of ions and the degree of wear out of the annular member 80. In addition, the radial dimension from the end portion of the conductive member 81 on the inner peripheral surface 80b1 side, the length L, may be determined so as to cover the worn-out portion according to the worn-out situation of the annular member 80. In addition, the edge ring 30 and the annular member 80 are not limited to an integral member, but may be configured with a plurality of members.

In addition, it should be understood that the ring assembly, the substrate support, and the substrate processing apparatus according to the above-described embodiments are examples in all respects and are not restrictive. The above-described embodiments can be modified and improved in various forms without departing from the scope and spirit of the appended claims. The matters described in the above-described plurality of embodiments can have other configurations as long as the configurations do not conflict with each other, and the matters can be combined with each other as long as the configurations do not conflict.

The substrate processing apparatuses according to the disclosure can be applied to any type of a capacitively coupled plasma (CCP), an inductively coupled plasma (ICP), a radial line slot antenna (RLSA), an electron cyclotron resonance plasma (ECR), or a helicon wave plasma (HWP).

According to the disclosure, adjustment of an angle of incidence of ions is achieved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A ring assembly comprising:
a conductive edge ring;
an insulating annular member including at least an inner peripheral portion disposed on the edge ring; and
a conductive member disposed on at least a portion of an upper surface of the annular member overlapping with the edge ring in a top plan view.

2. The ring assembly according to claim 1, wherein an inner diameter of the annular member is larger than an inner diameter of the edge ring.

3. The ring assembly according to claim 1, wherein an inner diameter of the conductive member is equal to the inner diameter of the annular member.

4. The ring assembly according to claim 1, wherein an outer diameter of the conductive member is smaller than an outer diameter of the annular member.

5. The ring assembly according to claim 1, wherein the edge ring is made of silicon or silicon carbide.

6. The ring assembly according to claim 1, wherein the annular member is made of silicon oxide.

7. The ring assembly according to claim 1, wherein the conductive member is made of silicon or silicon carbide.

8. The ring assembly according to claim 1, wherein the conductive member is annular or arc-shaped.

9. The ring assembly according to claim 1, wherein the conductive member covers the upper surface of the annular member overlapping with the edge ring in top plan view.

10. The ring assembly according to claim 1, wherein the conductive member covers the upper surface of the annular member that overlapping with the edge ring in a predetermined range from the inner diameter side in top plan view.

11. A substrate support assembly comprising:
a substrate support configured to support a substrate; and
a ring assembly,
wherein the ring assembly comprises:
a conductive edge ring supported on an outer periphery of the substrate support and surrounding the substrate;
an insulating annular member including at least an inner peripheral portion disposed on the edge ring; and
a conductive member disposed on at least a portion of an upper surface of the annular member overlapping with the edge ring in top plan view.

12. A substrate processing apparatus comprising a chamber and a substrate support assembly,
wherein the substrate support assembly comprises:
a substrate support configured to support a substrate; and
a ring assembly,
wherein the ring assembly comprises:
a conductive edge ring supported on an outer periphery of the substrate support and surrounding the substrate;
an insulating annular member including at least an inner peripheral portion disposed on the edge ring; and
a conductive member disposed on at least a portion of an upper surface of the annular member overlapping with the edge ring in top plan view.
